(19) United States
(12) Patent Application Publication
(10) Pub. No.: US 2003/0042498 A1
(43) Pub. Date: Mar. 6, 2003

(54) Method of forming a substrate-triggered SCR device in CMOS technology

(76) Inventors: Ming-Dou Ker, Hsin-Chu City (TW); Tung-Yang Chen, Hsin-Chu City (TW); Tien-Hao Tang, Hsin-Chu City (TW)

Correspondence Address: NAIPO (NORTH AMERICA INTERNATIONAL PATENT OFFICE), P.O. BOX 506, MERRIFIELD, VA, 22116, US

(21) Appl. No.: 09/682,400

(22) Filed: Aug. 30, 2001

(51) Int. Cl. H01L 29/74; H01L 31/111; H01L 23/62

(52) U.S. Cl. 257/173; 257/355; 257/356; 257/360; 257/361; 257/362

(57) ABSTRACT

A P_STSCR structure includes a P-type substrate, an N-well in the P-type substrate, a first N⁺ diffusion region located in the P-type substrate connected to the cathode, a second P⁺ diffusion region located in the N-well connected to the anode, and a third P⁺ diffusion region as a trigger node located in the P-type substrate and between the first N⁺ diffusion region and the second P⁺ diffusion region. A lateral SCR device including the second P⁺ diffusion region, the N-well, the P-type substrate and the first N⁺ diffusion region is thereby formed. When a current flows from the trigger node into the P-type substrate, the lateral SCR device is triggered on into its latch state to discharge ESD current. Since the present invention utilizes a substrate-triggered current I_{trig} flowing into or flowing out from the P-type substrate or the N-well through the inserted trigger node, a much lower switching voltage in the SCR device is obtained.With such a lower switching voltage in the SCR device, the total layout area of the ESD protection circuit can be reduced, and the turn-on speed of SCR device is further improved to quickly discharge ESD current.ESD current flowing through surface channels, and heat dissipation issues, are avoided, while presenting no increase to the overall complexity and difficulty of CMOS IC manufacturing.

### BACKGROUND OF THE INVENTION

1. Field of the Invention

The present invention provides a method for making a silicon controlled rectifier(SCR) device utilizing in electrostatic discharge (ESD) protection circuits. In particular, a silicon controlled rectifier device structure with substrate-triggered effect.

2. Description of the Prior Art

With the continued scaling down of semiconductor integrated circuit (IC) devices, the present trend is moving towards production of semiconductor integrated circuits having very small sizes in the advanced sub-quarter-micron CMOS technologies. It is consequently increasingly important to build electrostatic discharge (ESD) protection circuits on the chip to protect the devices and circuits of the IC against ESD-related damage. The ESD robustness of commercial IC products is generally needed to be higher than 2 kV in the human-body-model (HBM) ESD stress. While withstanding ESD overstress, it is desired that the on-chip ESD protection circuits have relatively small dimensional requirements to save silicon area. With respect to this issue, heat dissipation issues become paramount. When designing an ESD protection circuit on the chip with specific device, the specific device should not occupy a large layout area and should have a low holding voltage, since dissipated ESD power is equal to the product of the holding voltage of the specific device with the ESD current (Power=I_{ESD}*V_{hold}).

Lateral silicon controlled rectifier (SCR) devices are used in input/output ESD protection circuits, as well as in V_{DD}-to-V_{SS} ESD clamp circuits, to effectively protect CMOS ICs against ESD damage. An important characteristic of SCR devices is the low holding voltage (V_{hold}), at about 1 V, in CMOS processes. These devices thus exhibit a lower power dissipation than other devices, such as diode, MOS transistor, bipolar junction transistor, and field-oxide devices, which are used in other ESD protection circuit designs for CMOS technologies. For example, the holding voltage of a SCR device in a 0.5 μm CMOS process is about 1 V, but the snapback holding voltage of an NMOS in the same process is about 10 V. Hence, the SCR device can sustain about 10 times more ESD voltage in an unit of layout area than the NMOS. While SCR devices have been used as the primary ESD clamping devices in some input ESD protection circuits, a secondary protection circuit needed to be added to enable complete ESD protection, because SCR devices often have a relatively higher trigger voltage (about 30˜50 V) in submicron CMOS technologies. This high trigger voltage is generally greater than the gate-oxide breakdown voltage (15˜20 V) of the input stages.

In U.S. Pat. No. 4,896,243, U.S. Pat. No. 5,012,317 and U.S. Pat. No. 5,336,908, a lateral silicon controlled rectifier (LSCR), as applied to an input ESD protection circuit, is proposed. Please refer to FIG. 1(a) to FIG. 1(c). FIG. 1(a) is a schematic diagram of the LSCR device applied to an input ESD protection circuit according to the prior art. FIG. 1(b) is a graph of the I-V characteristics of the LSCR device according to the prior art. FIG. 1(c) is a schematic diagram of the device structure of the LSCR device according to the prior art. As shown in FIG. 1(a), the input ESD protection circuit 10 comprises an input pad 11, an internal circuit 12 electrically connected to both a V_{DD} power terminal and a V_{SS} power terminal, and a conductor 13 electrically connected to the input pad 11 and the internal circuit 1 2. An LSCR device 14, comprising a P⁺ region 14a, an N-well 14b, a P-type substrate 14c, and an N region 14d, is located between the input pad 11 and the internal circuit 12 and electrically connected to the conductor 13 to provide ESD protection. A secondary protection circuit 15 comprises a series resistor 16 and a gate-grounded NMOS 17, and is located between the LSCR device 14 and the internal circuit 12. As shown in FIG. 1(b), the LSCR device 14 has an obviously higher trigger voltage of about 35 V in a typical 0.35 μm CMOS process, which is generally greater than the gate-oxide breakdown voltage(15 V˜20 V) of the input stage in submicron CMOS IC″s. The secondary protection circuit 15 is thus used to sustain the ESD stress before the LSCR triggers on to bypass the ESD current on the input pad 11. As shown in FIG. 1(c), the LSCR device structure 14 is made in a P-type substrate 21. The LSCR device 14 comprises an N-well 22 in the P-type substrate 21, a P⁺ region 24 in the N-well 22 electrically connected to the input pad 23, and an N⁺ region 25 in the P-type substrate 21 electrically connected to ground. The P⁺ region 24, the N-well 22, the P-type substrate 21 and the N⁺ region 25 together form an LSCR device. When the LSCR device is triggered on, ESD current flows via the P⁺ region 24 through the N-well 22, through the P-type substrate 21, through the N⁺ region 25, and then to ground for discharging.

If the LSCR device 14 does not trigger on in a sufficiently rapid manner, the secondary protection circuit 15 may be damaged by the ESD energy. In consideration of this issue, the secondary protection circuit 15 is designed with a considerably large device dimensionality and a large series resistor for protection, and thus often occupies more layout area. Also, if the secondary protection circuit 15 is not properly designed, it will cause window failure in ESD test scanning from a low voltage to a high voltage. Such input ESD protection circuits were found to pass ESD stresses with low voltage levels or high voltage levels, but failed under tests with mid-ranged ESD stress voltage levels.

In order to provide more effective ESD protection for input stages, a modified lateral SCR (MLSCR) device was proposed to reduce the trigger voltage of the lateral SCR. In U.S. Pat. No. 4,939,616, U.S. Pat. No. 5,343,053, and U.S. Pat. No. 5,430,595, a modified lateral silicon controlled rectifier (MLSCR) with a lower trigger voltage and smaller device dimensions for layout of the secondary protection circuit is proposed for application in an input ESD protection circuit. Please refer to FIG. 2(a) to FIG. 2(c). FIG. 2(a) is a schematic diagram of an MLSCR device applied to an input ESD protection circuit according to the prior art. FIG. 2(b) is a graph of the I-V characteristics of the MLSCR device according to the prior art. FIG. 2(c) is a schematic diagram of the device structure of the MLSCR device according to the prior art. As shown in FIG. 2(a), the input ESD protection circuit 30 comprises an input pad 31, an internal circuit 32 electrically connected to both a V_{DD} power terminal and a V_{SS} power terminal, and a conductor 33 electrically connected to the input pad 31 and the internal circuit 32. An MLSCR device 34 comprising a P⁺ region 34a, an N-well 34b, a P-type substrate 34c, and an N⁺ region 34d is located between the input pad 31 and the internal circuit 32 and electrically connected to the conductor 33 to provide ESD protection. An N⁺ diffusion region 34e is added across the N-well 34b and P-type substrate 34c junction. A secondary protection circuit 35 comprises a series resistor 36 and a gate-grounded NMOS 37, and is located between the MLSCR device 34 and the internal circuit 32. Since the N⁺ diffusion region 34e has a much higher doping concentration than the N-well 34b, the breakdown voltage across the N-well 34b and the P-type substrate 34c junction is lowered, which cause the trigger voltage of the MLSCR device 34 to be much lower than that of the LSCR in an identical CMOS process.

As shown in FIG. 2(b), the MLSCR device 34 has a trigger voltage of about 10 V in a typical 0.35 μm CMOS process.As shown in FIG. 2(c), the MLSCR device 40 structure is made in a P-type substrate 41. The MLSCR device 40 comprises an N-well 42 in the P-type substrate 41, a P⁺ region 44 in the N-well 42 that is electrically connected to the input pad 43, an N⁺ region 45 in the P-type substrate 41 that is electrically connected to ground, and an additional N⁺ diffusion region 46 across the N-well 42 and the P-type substrate 41. The P⁺ region 44, the N-well 42, the P-type substrate 41, the N⁺ region 45 and the additional N⁺ diffusion region 46 together form an MLSCR device. Although the trigger voltage of the MLSCR device 34 is considerably lower, cooperation with the secondary protection circuit 35 is still required to provide safe protection for the gates of the input circuits, and for performing the overall ESD protection function for the input stage. Unsuitable design or layout of the secondary protection circuit 35 still cause ESD damage in the secondary protection circuit 35, rather than in the MLSCR device 34.

In order to effectively protect input stages, and even output buffers, in submicron CMOS IC″s, a low-voltage-trigger silicon controlled rectifier (LVTSCR) device has been invented. This design is disclosed in U.S. Pat. No. 5,465,189 and U.S. Pat. No. 5,576,557. Please refer to FIG. 3(a) to FIG. 3(c). FIG. 3(a) is a schematic diagram of an LVTSCR device applied to an output ESD protection circuit according to the prior art. FIG. 3(b) is a graph of the I-V characteristics of the LVTSCR device according to the prior art. FIG. 3(c) is a schematic diagram of the device structure of the LVTSCR device according to the prior art. As shown in FIG. 3(a), an output ESD protection circuit 50 comprises an output pad 51, an internal circuit 52 electrically connected to both a V_{DD} power terminal and a V_{SS} power terminal, and a conductor 53 electrically connected the output pad 51 and the internal circuit 52. An LVTSCR device 54 comprises a P⁺ region 54a, an N-well 54b, a P-type substrate 54c, and an N⁺ region 54d that is located between the input pad 51 and the internal circuit 52 and electrically connected to the conductor 53 to provide ESD protection. A short channel NMOS device 55 is inserted into the LVTSCR device structure, and thus the trigger voltage of the LVTSCR 54 is equivalent to the snapback-trigger voltage of the short-channel NMOS device 55.

With a suitable design, the trigger voltage of the LVTSCR device 54 can be lowered to below the breakdown voltage of the output NMOS. As shown in FIG. 3(b), the LVTSCR device 54 has a trigger voltage of about 8 V in a typical 0.35 μm CMOS process.As shown in FIG. 3(c), the LVTSCR device 60 structure is made in a P-type substrate 61. The LVTSCR device 60 comprises an N-well 62 in the P-type substrate 61, a P⁺ region 64 in the N-well 62 that is electrically connected to the output pad 63, an N⁺ region 65 in the P-type substrate 61 that is electrically connected to ground, and an additional N⁺ diffusion region 66 that is across the N-well 62 and the P-type substrate 61. The P⁺ region 64, the N-well 62, the P-type substrate 61 and the N⁺ region 65 together form a lateral SCR device. A gate 67 is made between the N⁺ diffusion region 66 and the N⁺ region 65 to complete the structure of a short channel NMOS device. The lateral SCR device and the inserted short channel NMOS device together form the structure of an LVTSCR device. Since the trigger voltage of the LVTSCR device 60 is very low, it can provide effective ESD protection for the input stages or the output buffers of CMOS ICs, without the need for a secondary protection circuit. The total layout area of the ESD protection circuit using the LVTSCR can thus be significantly reduced. Although the LVTSCR device 60 has a very low trigger voltage, a device design for an ESD protection circuit that achieves an even lower trigger voltage is desired. Such a device should also not present additional complexity and difficulty to the CMOS IC manufacturing process.

To effectively protect the thinner gate oxides of very deep submicron CMOS ICs, a gate-coupled technique is used to further reduce the trigger voltage of the LVTSCR. This design is disclosed in U.S. Pat. No. 5,400,202 and U.S. Pat. No. 5,528,188. Please refer to FIG. 4. FIG. 4 is a schematic diagram of a gate-coupled LVTSCR device applied to an input ESD protection circuit according to the prior art. As shown in FIG. 4, an ESD protection circuit design 70 comprises a lateral SCR 72. The lateral SCR 72 further comprises a P⁺ region 73, an N-well 74, a P-type substrate 75 and an N⁺ region 76. A short-channel NMOS device 77 is inserted across the N-well 74 and the N⁺ region 76. The lateral SCR 72 and the short-channel NMOS device 77 together make up an LVTSCR device 78.The gate 79 of the short-channel NMOS device 77 is biased by a gate-biasing circuit. The gate-biasing circuit includes a capacitor 81 connected from the pad 80 to the gate 79, and a resistor 82 connected from the gate 79 to a V_{SS} power terminal. An internal circuit 84 is electrically connected between the V_{SS} power terminal and the V_{DD} power terminal, and is electrically connected to the pad 80 via a conductor 83. Also, the anode of the lateral SCR 72 is electrically connected to the conductor 83, and the cathode of the lateral SCR 72 is electrically connected to the V_{SS} power terminal.

The trigger voltage of the gate-coupled LVTSCR is much lowered by the coupled voltage on the gate of the short-channel NMOS device 77. The thinner gate oxides of the input stages in very deep submicron CMOS ICs are therefore effectively protected by this technique, but the over-high gate bias also causes the ESD current to flow through the inversion layer of the surface channel of the short-channel NMOS device 77, and may easily cause heat dissipation problems and damage of the short-channel NMOS device 77.

The above-mentioned SCR devices for ESD protection circuits all have disadvantages, and this fact presents limitations for applications in modern circuits. For this reason, ESD protection SCR devices using gate-driven techniques and adding diffusion regions across junctions may not be suitable for improving ESD robustness in sub-quarter-micron CMOS technologies.

It is hence important to develop an ESD protection SCR design that further reduces the trigger voltage of the SCR element by utilizing substrate-triggered technique and improves the turn-on speed of the SCR element, while also providing savings in the total layout area of the ESD protection circuit. Such a circuit should avoid the above-mentioned current flowing through the surface channel, and heat dissipation issues, and should not present additional complexity and difficulty to CMOS IC manufacturing process.

### SUMMARY OF INVENTION

It is therefore a primary objective of the present invention to provide a design and method of forming an ESD protection lateral silicon controlled rectifier (lateral SCR) device, and in particular, a substrate-triggered LSCR device, so as to improve the design flexibility of on-chip ESD protection circuits and to improve the ESD level of the related IC products.

The method according to the present invention involves inserting an extra P⁺ diffusion region into the SCR device structure. The inserted P⁺ diffusion connects as a trigger node of a P-type substrate-triggered SCR (P_STSCR) device. When a current flows from the trigger node (the inserted P⁺diffusion) into the P-type substrate, the lateral SCR is triggered on into its latch state. A higher substrate-triggered current leads to a much lower switching voltage in the P_STSCR device. With a lower switching voltage in the SCR device, the turn-on speed of the SCR device is further improved to quickly discharge ESD current. When the substrate-triggered diffusion is an N-type diffusion, the SCR device is defined as an N-type substrate-triggered SCR device (N_STSCR). By utilizing the device structure according to the present invention, the effect of the circuit design used for on-chip ESD protection is significantly increased.

It is an advantage of the present invention that in the design and method for making the ESD protection SCR device, the substrate-triggered current I_{trig} flows into or flows out from the P-type substrate through the trigger node. Therefore, the lateral SCR is triggered on into its latch state and leads to a much lower switching voltage in the SCR device. With a much lower switching voltage in the SCR device, the total layout area of the ESD protection circuit may be reduced, and the turn-on speed of SCR device can be further improved to quickly discharge ESD current.Also, ESD current flowing through the surface channel, and heat dissipation problems, are avoided, while the complexity and difficulty in CMOS IC manufacturing is not increased.

These and other objectives of the present invention will no doubt become obvious to those of ordinary skill in the art after reading the following detailed description of the preferred embodiment, which is illustrated in the various figures and drawings.

### BRIEF DESCRIPTION OF DRAWINGS

FIG. 1(a) is a schematic diagram of an LSCR device applied to an input ESD protection circuit according to the prior art.

FIG. 1(b) is a graph of the I-V characteristics of an LSCR device according to the prior art.

FIG. 1(c) is a schematic diagram of a device structure of an LSCR device according to the prior art.

FIG. 2(a) is a schematic diagram of an MLSCR device applied to an input ESD protection circuit according to the prior art.

FIG. 2(b) is a graph of the I-V characteristics of the MLSCR device according to the prior art.

FIG. 2(c) is a schematic diagram of the device structure of an MLSCR device according to the prior art.

FIG. 3(a) is a schematic diagram of an LVTSCR device applied to an output ESD protection circuit according to the prior art.

FIG. 3(b) is a graph of the I-V characteristics of an LVTSCR device according to the prior art.

FIG. 3(c) is a schematic diagram of the device structure of an LVTSCR device according to the prior art.

FIG. 4 is a schematic diagram of a gate-coupled LVTSCR device applied to an input ESD protection circuit according to the prior art.

FIG. 5(a) is a cross-sectional schematic diagram of a P-type substrate-triggered SCR device(P_STSCR) structure according to the present invention.

FIG. 5(b) is a schematic diagram of a corresponding symbol for the P_STSCR device according to the present invention.

FIG. 6(a) is a schematic diagram of an experimental setup to measure the I-V characteristics of the P_STSCR device according to the present invention.

FIG. 6(b) illustrates measured results of the I-V characteristics of a P_STSCR device according to the present invention.

FIG. 7 is a graph of the dependence of a switching voltage of a P_STSCR device on a substrate triggered current.

FIG. 8(a) is a cross-sectional schematic diagram of a modified design of a P-type substrate-triggered SCR device structure according to the present invention.

FIG. 8(b) is a diagram of a corresponding symbol for a modified design of a P_STSCR device, called as P_STMLSCR device.

FIG. 9(a) is a schematic diagram of an experimental setup to measure the I-V characteristics of a P_STMLSCR device according to the present invention.

FIG. 9(b) illustrates measured results of the I-V characteristics of a P_STMLSCR device according to the present invention.

FIG. 10 is a graph of the dependence of a switching voltage of a P_STMLSCR device on a substrate triggered current.

FIG. 11(a) is a cross-sectional schematic diagram of a P-type substrate-triggered SCR device structure with a reduced device size according to the present invention.

FIG. 11(b) is a diagram of a corresponding symbol for a P-type substrate-triggered SCR device structure with a reduced device size according to the present invention.

FIG. 12(a) is a cross-sectional schematic diagram of an N-type substrate-triggered SCR device(N_STSCR) structure according to the present invention.

FIG. 12(b) is a diagram of a corresponding symbol for an N-type substrate-triggered SCR device structure according to the present invention.

FIG. 13(a) is across-sectional schematic diagram of a modified N_STSCR device structure according to the present invention.

FIG. 13(b) is a diagram of a corresponding symbol for a modified N_STSCR device structure according to the present invention.

FIG. 14(a) is across-sectional schematic diagram of an N_STSCR device structure with a reduced layout spacing according to the present invention.

FIG. 14(b) is a diagram of a corresponding symbol for an N_STSCR device structure with a reduced layout spacing according to the present invention.

FIG. 15(a) is across-sectional schematic diagram of a double-triggered SCR device(DT_SCR) according to the present invention.

FIG. 15(b) is a diagram of a corresponding symbol for a double-triggered SCR device according to the present invention.

FIG. 16(a) is across-sectional schematic diagram of a modified DT_SCR device structure according to the present invention.

FIG. 16(b) is a diagram of a corresponding symbol for a modified DT_STSCR device structure according to the present invention.

FIG. 17(a) is across-sectional schematic diagram of a modified DT_SCR device structure according to the present invention.

FIG. 17(b) is a diagram of a corresponding symbol for a modified DT_STSCR device structure according to the present invention.

FIG. 18 is a schematic diagram of a P_STSCR device with a gate poly to block a field-oxide region.

FIG. 19 is a schematic diagram of an N_STSCR device with a gate poly to block a field-oxide region.

FIG. 20 to FIG. 22 are schematic diagrams of a DT_SCR device structure with a poly gate to block a field-oxide region.

FIG. 23 to FIG. 25 are schematic diagrams of a modified DT_SCR device with a poly gate to block a field-oxide region.

FIG. 26 to FIG. 28 are schematic diagrams of a DT_SCR device with two poly gates to block a field oxide region.

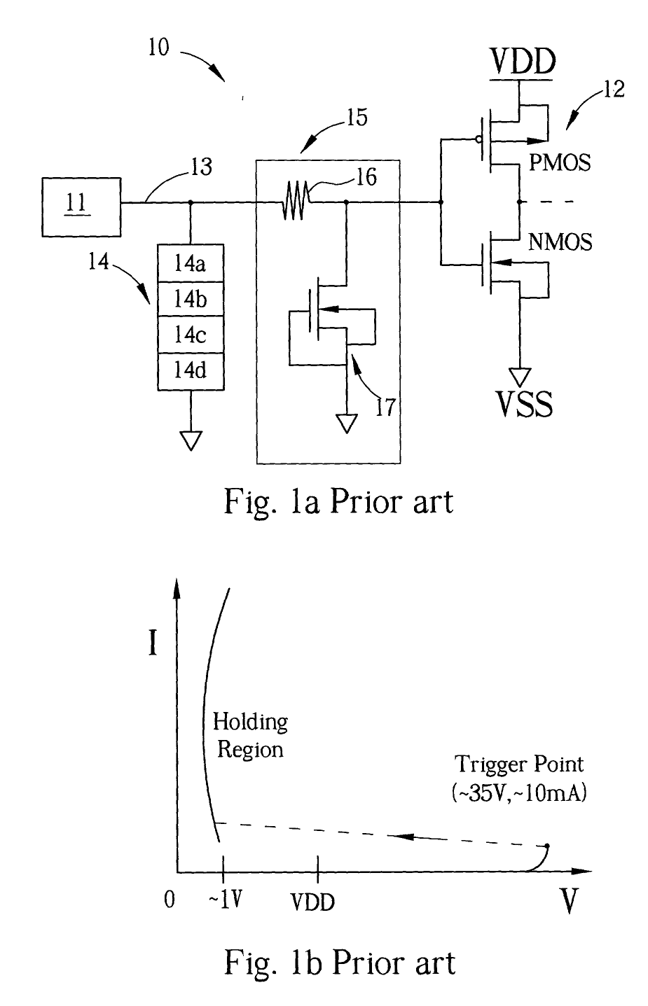

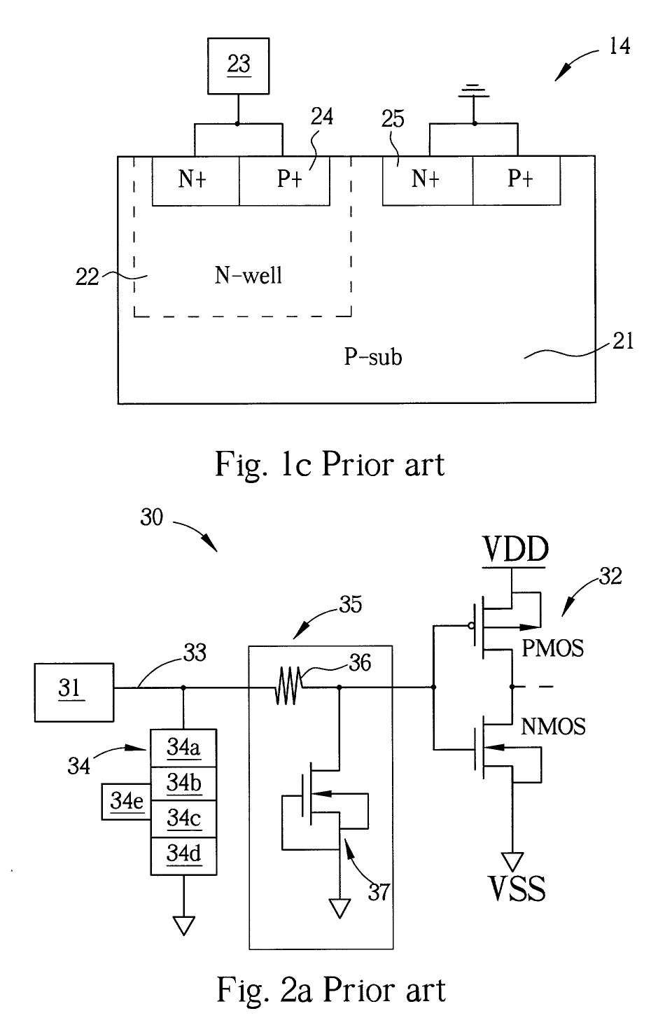

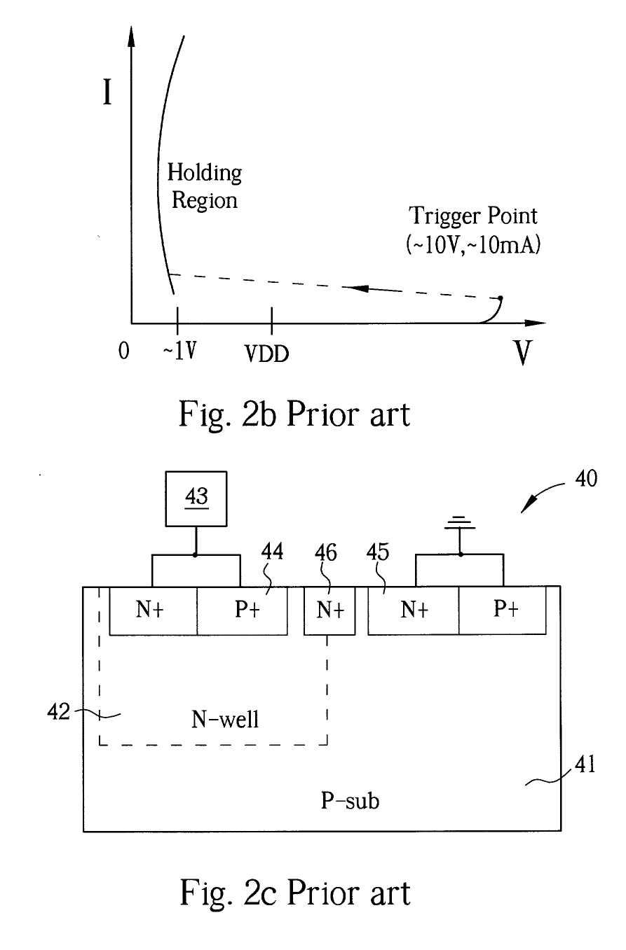

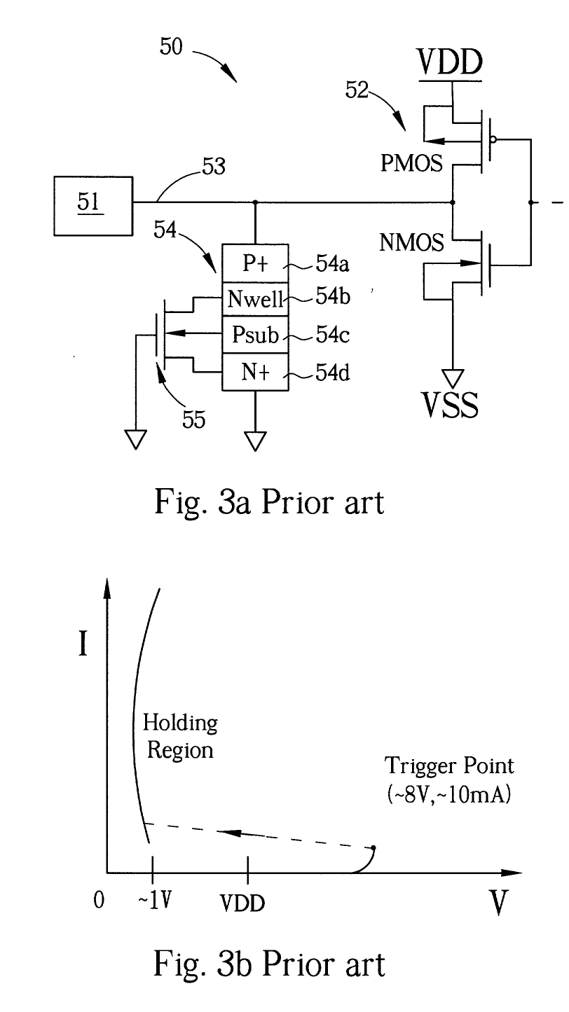

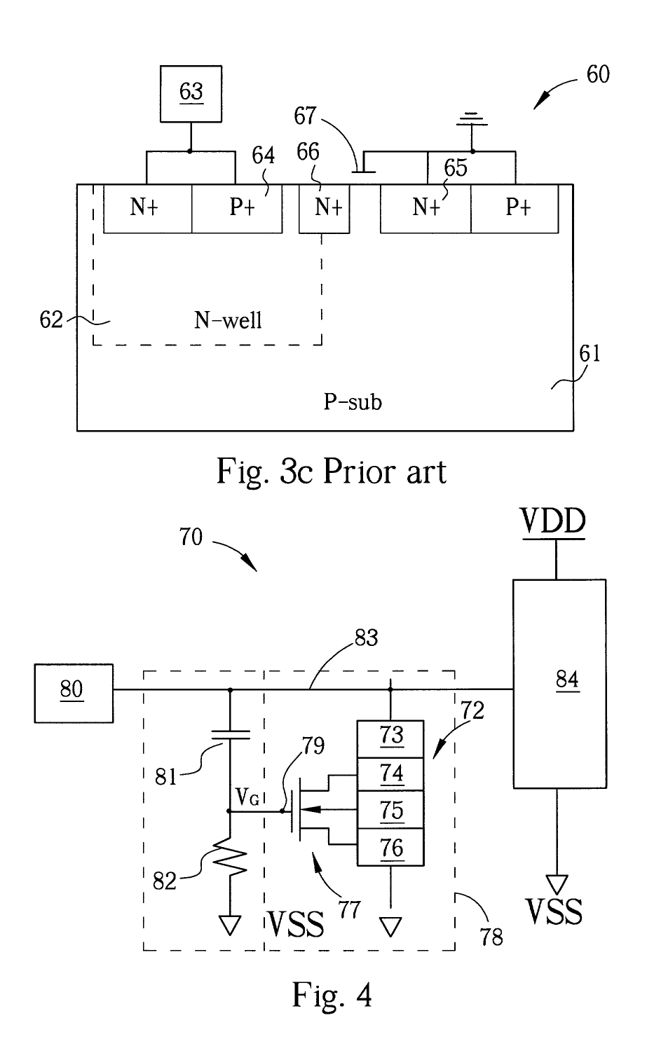

### DETAILED DESCRIPTION

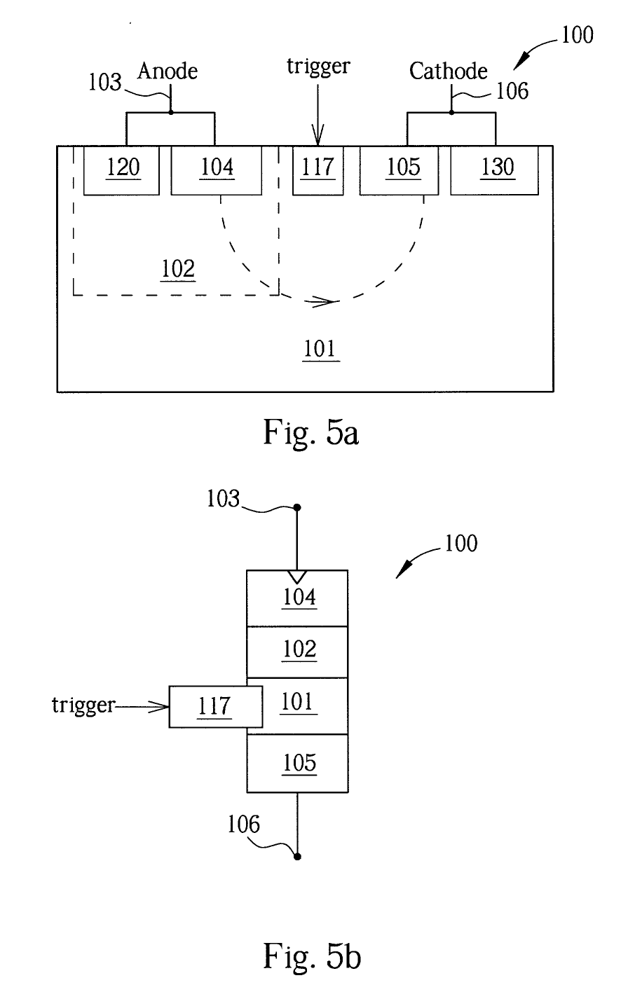

Please refer to FIG. 5(a) to 5(b). FIG. 5(a) is a cross-sectional schematic diagram of a P-type substrate-triggered SCR (P_STSCR) device 100 according to the present invention. FIG. 5(b) is a diagram of a corresponding symbol for the P_STSCR device 100. As shown in FIG. 5(a), the P_STSCR device 100 is made in a P-type silicon substrate 101. The P_STSCR device 100 comprises an N-well 102. A P⁺ region 104 and an N⁺ region 120 in the N-well 102 are electrically connected to an anode 103. A P⁺ region 130 and an N⁺ region 105 in the P-type substrate 101 are electrically connected to a cathode 106. A P⁺ diffusion 117 is use as a trigger node of the P_STSCR device 100. The P⁺ region 104, the N-well 102, the P-type substrate 101 and the N⁺ region 105 together form an LSCR device. When a current flows from the trigger node (i.e., the inserted P⁺ diffusion 117) into the P-type substrate 101, the lateral SCR is triggered on into its latch state to provide a low impedance path to discharge ESD current from the anode 103 to the cathode 106. As shown in FIG. 5(b), the anode 103 is indicated by an arrow into the device symbol, whereas the cathode 106 has no arrow in the symbol.

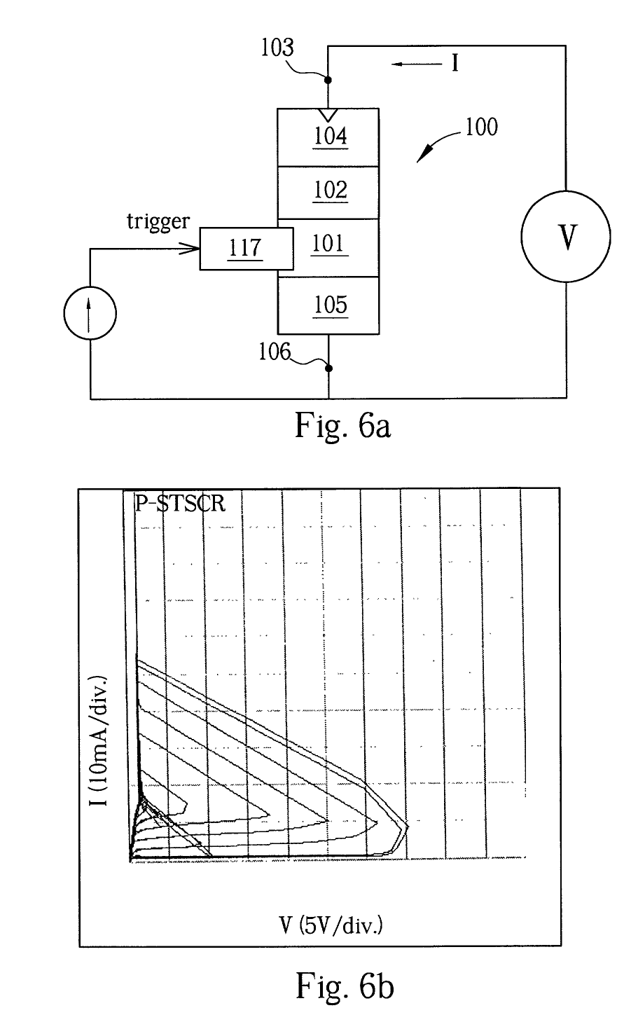

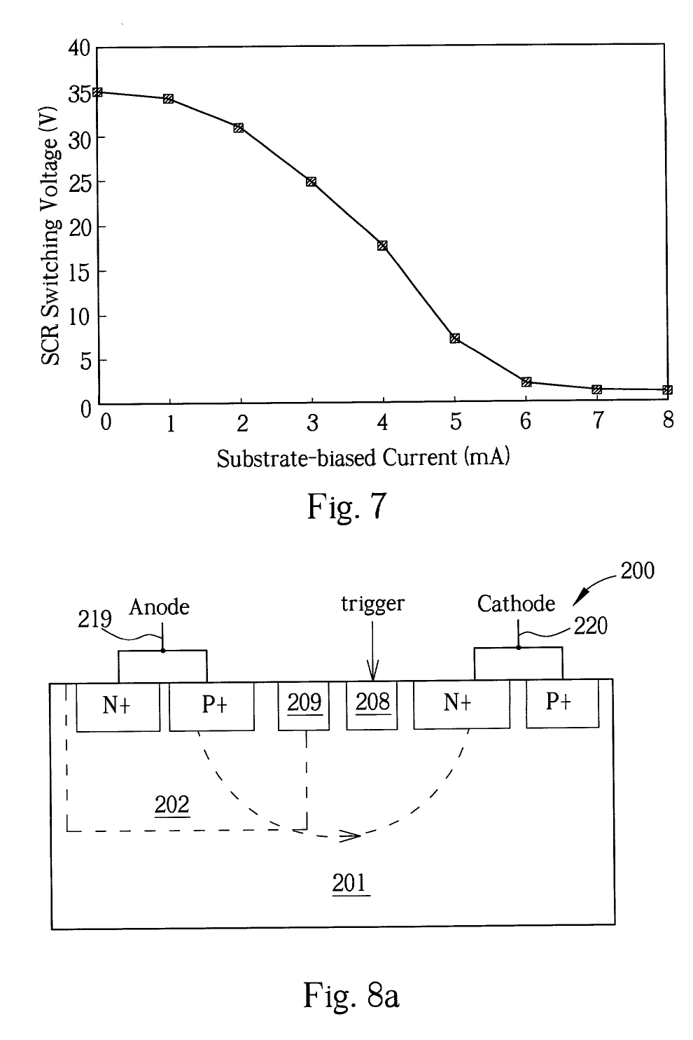

Such a P-type substrate-triggered SCR (P_STSCR) device has been laid out and fabricated in a 0.35 μm suicide CMOS process. Please refer to FIG. 6(a) and FIG. 6(b). FIG. 6(a) is a schematic diagram of an experimental setup to measure the I-V characteristics of the P_STSCR device according to the present invention. FIG. 6(b) illustrates the measured results of the I-V characteristics of the P_STSCR device according to the present invention. As shown in FIG. 6(a), an external voltage is applied between the anode 103 and the cathode 106 through the external circuit. A biasing current (I_{bias}) flows from the trigger node (i.e., the inserted P⁺ diffusion 117) into the P-type substrate 101 through another external circuit. As shown in FIG. 6(b), the trigger current applied to the trigger node has a stepping of 1 mA. When the P_STSCR device has no substrate-triggered current (I_{bias}=0), the P_STSCR is turned on by its well/substrate junction breakdown. The switching voltage of the fabricated P_STSCR device is as high as 35 V when the substrate-triggered current is zero. But the switching voltage of the fabricated P_STSCR device is reduced to 7.4 V when the substrate-triggered current is 5 mA. Moreover, the switching voltage of the fabricated P_STSCR device is reduced to only 1.35 V when the substrate-triggered current is 7 mA. Please refer to FIG. 7. FIG. 7 is a graph of the dependence of the switching voltage of the P_STSCR device on the substrate-triggered current. A higher substrate-triggered current leads to a much lower switching voltage in the P_STSCR device. With a lower switching voltage in the P_STSCR device, the turn-on speed of the P_STSCR device is further improved to quickly discharge ESD current. This is a very excellent feature of this P_STSCR device for use in an on-chip ESD protection circuit.

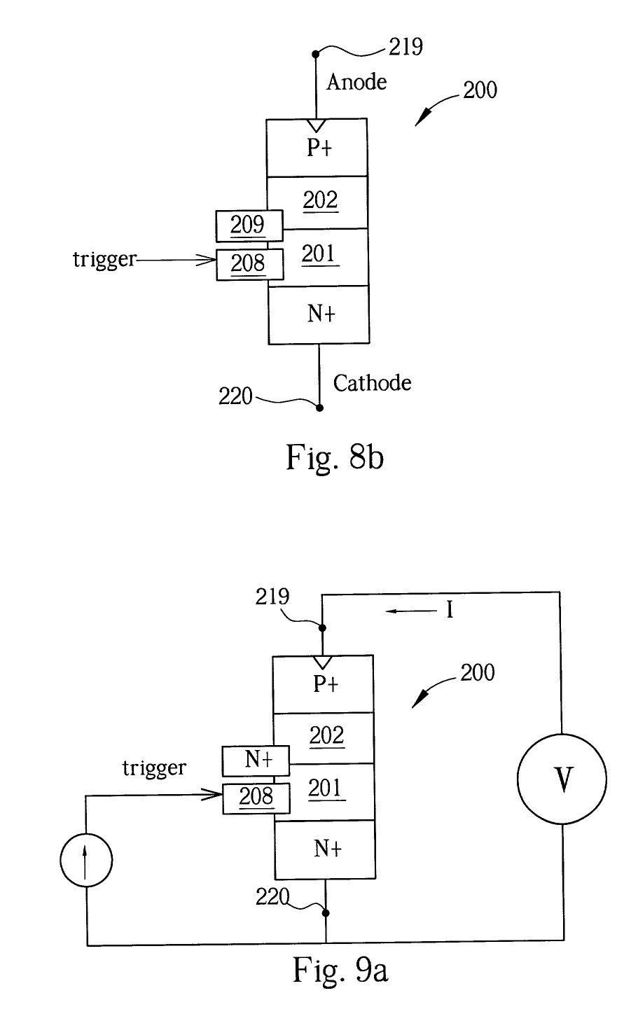

Please refer to FIG. 8(a) to 8(b). FIG. 8(a) is a cross-sectional schematic diagram of a modified design of a P-type substrate-triggered SCR device 200 according to the present invention. FIG. 8(b) is a diagram of a corresponding symbol for the modified design of the P_STSCR device 200. In the following, the modified design of the P-type substrate-triggered SCR (P_STSCR) device is called as P_STMLSCR device. As shown in FIG. 8(a), the P_STMLSCR device 200 comprises a first N⁺ region and a first P⁺ region in the P-type substrate 201, that is electrically connected to a cathode 220. A second N⁺ region and a second P⁺ region in the N-well 202, that is electrically connected to an anode 219. An N⁺ diffusion 209 placed across the N-well 202 and the P-type substrate 201 junction to lower the breakdown voltage of the lateral SCR device, and an extra P⁺ diffusion 208 for use as a trigger node of the P_STMLSCR device 200. As shown in FIG. 8(b), the P_STMLSCR 200 comprises an N⁺ diffusion region 209 and a P⁺ diffusion region 208 inserted into the SCR device structure.

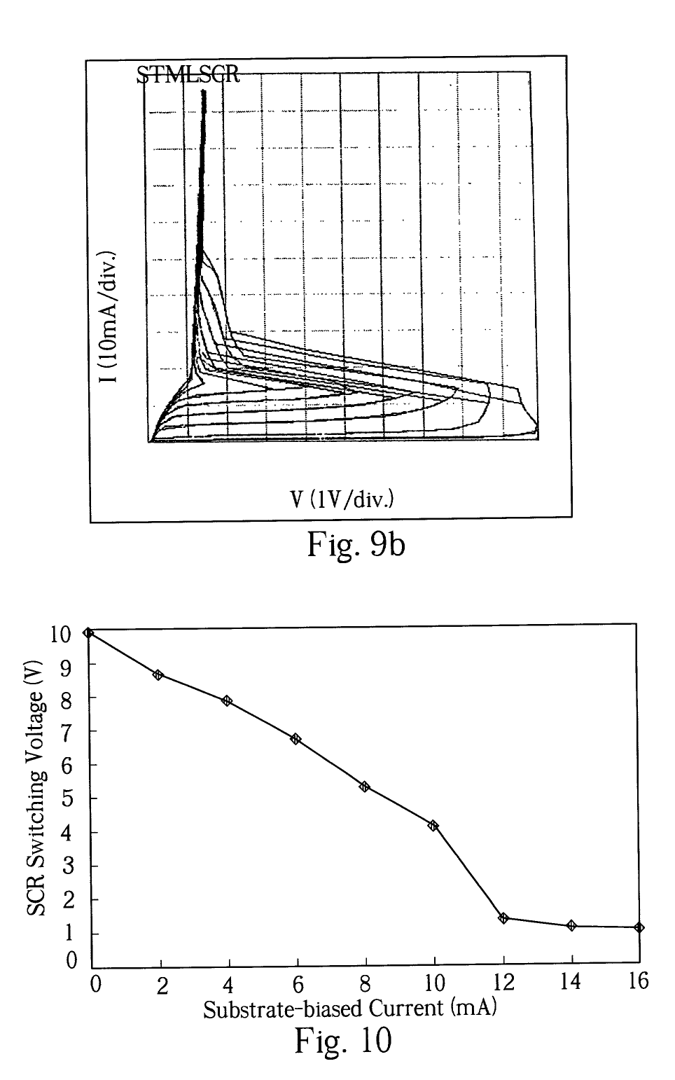

Please refer to FIG. 9(a) and FIG. 9(b). FIG. 9(a) is a schematic diagram of an experimental setup to measure the I-V characteristics of the P_STMLSCR device 200 according to the present invention. FIG. 9(b) illustrates measured results of the I-V characteristics of the P_STMLSCR device 200 according to the present invention. As shown in FIG. 9(a), an external voltage is applied between the anode 219 and the cathode 220 through the external circuit. A biasing current (I_{bias}) flows from the trigger node (the inserted P⁺ diffusion 208) into the P-type substrate 201 through another external circuit to turn on the P_STMLSCR device. As shown in FIG. 9(b), the trigger current applied to the trigger node has a step of 2 mA. When the P_STMLSCR device has no substrate-triggered current (I_{bias}=0), the P_STMLSCR is turned on by its well/substrate junction breakdown. The switching voltage of the fabricated P_STMLSCR device is 10 V when the substrate-triggered current is zero. But the switching voltage of the fabricated P_STMLSCR device is reduced to 4.1 V when the substrate-triggered current is 10 mA. Moreover, the switching voltage of the fabricated P_STMLSCR device is reduced to only 1.1 V when the substrate-triggered current is 14 mA. Please refer to FIG. 10. FIG. 10 is a graph of the dependence of the switching voltage of the P_STMLSCR device on the substrate triggered current. A higher the substrate-triggered current leads to a much lower switching voltage in the P_STMLSCR device. With a lower switching voltage in the P_STMLSCR device device, the turn-on speed of the P_STMLSCR device is further improved to quickly discharge ESD current.

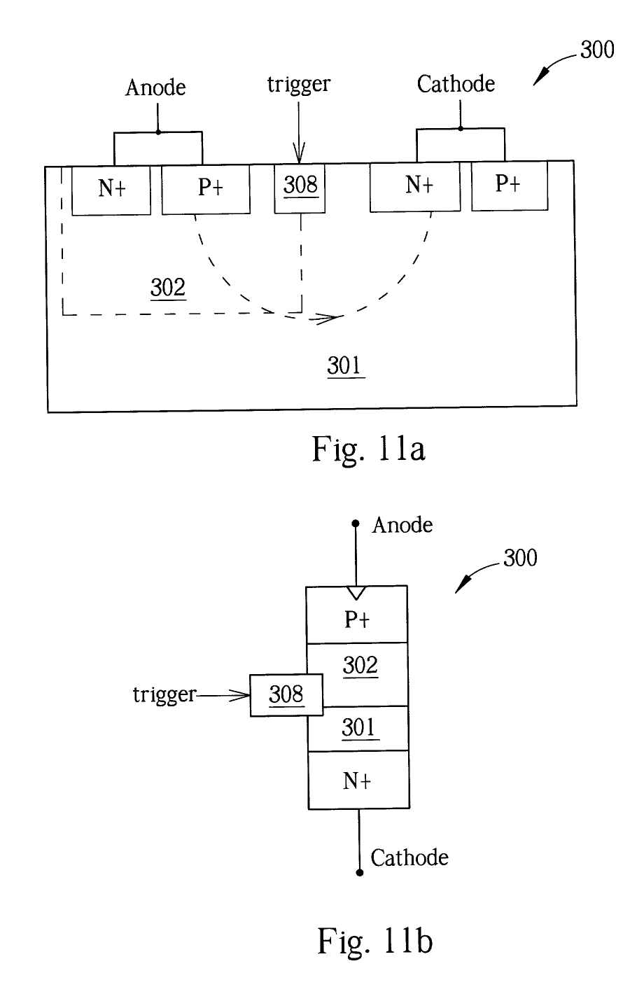

This substrate-triggered concept is applied to a lateral SCR device to generate different SCR device structures for ESD protection. In order to further reduce the device size from the anode to the cathode of the SCR device in silicon, the trigger node (the inserted P⁺ diffusion) is directly inserted across the junction between the N-well and P-type substrate. Please refer to FIG. 11(a) and FIG. 11(b). FIG. 11(a) is a cross-sectional schematic diagram of a P-type substrate-triggered SCR device 300 with a reduced device size according to the present invention. FIG. 11(b) is a diagram of a corresponding symbol for the P-type substrate-triggered SCR device 300. As shown in FIG. 11(a), an inserted P⁺ diffusion 308 is directly inserted across the junction between an N-well 302 and a P-type substrate 301, and serves as a trigger node. When a trigger current is applied to the P⁺ trigger node 308, the lateral SCR device is triggered on to provide a low-impedance path between the anode and cathode of the device 300. This characteristic is very useful for ESD-protection purposes. As shown in FIG. 11(b), the P_STSCR 300 comprises a P⁺ diffusion region 308 inserted across the junction between the N-well 302 and P-type substrate 301.

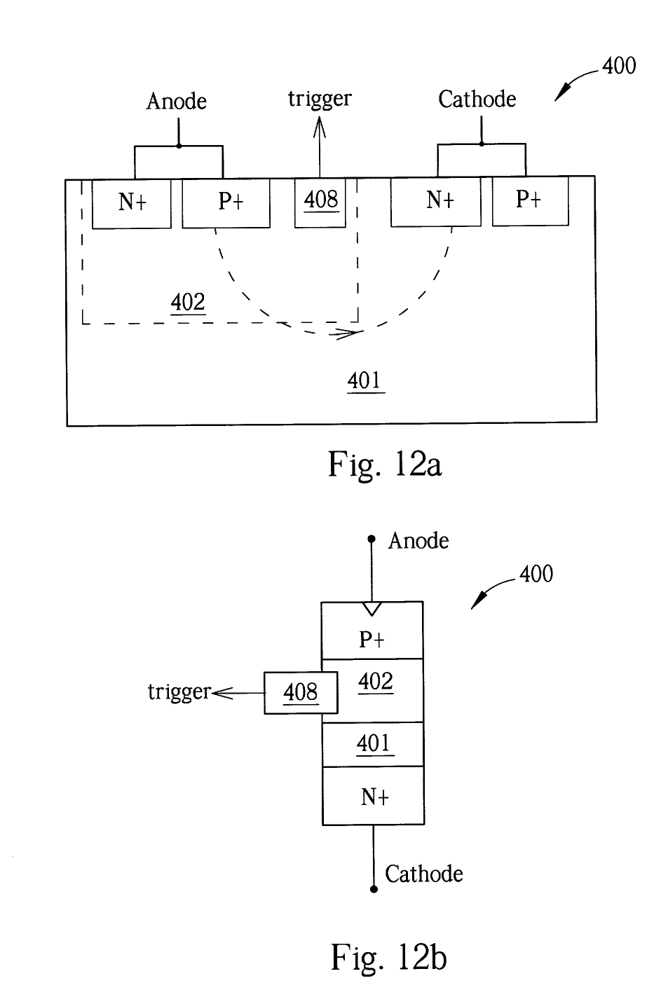

As compared to a P_STSCR structure that applies a trigger current into the P-type substrate to turn on the lateral SCR device, the SCR device may also be turned on if a trigger current flows out from the N-well of the SCR device. This design is called an N-type substrate-triggered SCR (N_STSCR) device in the present invention. Please refer to FIG. 12(a) and FIG. 12(b). FIG. 12(a) is a cross-sectional schematic diagram of an N-type substrate-triggered SCR device 400 according to the present invention. FIG. 12(b) is a diagram of a corresponding symbol for the N-type substrate-triggered SCR device 400. As shown in FIG. 12(a), when a trigger current flows out from the trigger node (an inserted N⁺ diffusion region 408 in the N-well region 402), the lateral SCR is triggered on into its latch state to provide a low impedance path from an anode to a cathode of the device 400. As shown in FIG. 12(b), the N_STSCR 400 comprises a N⁺ diffusion 408 inserted in an N-well 402.

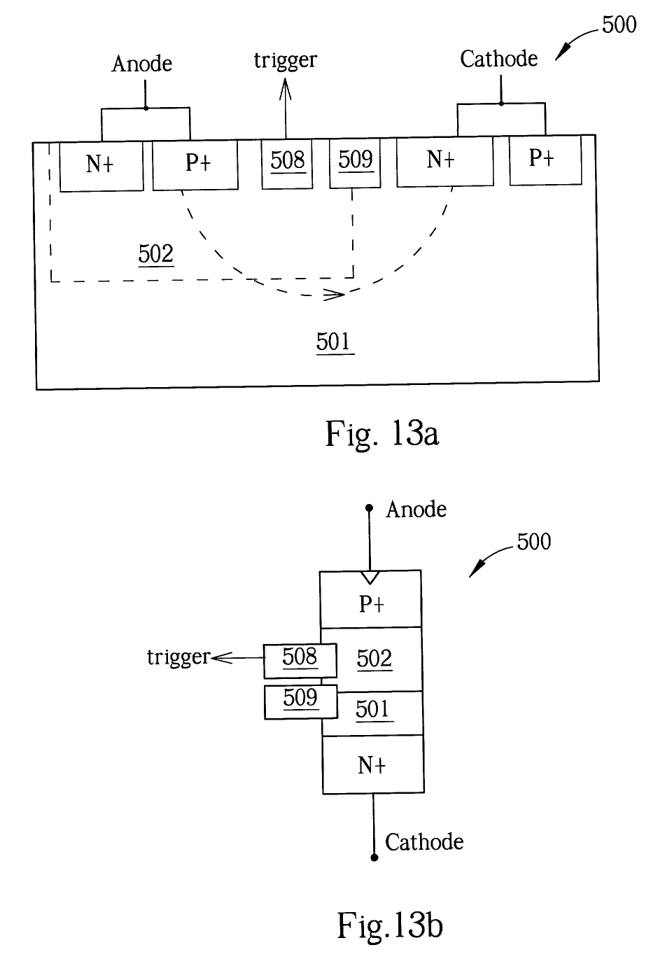

Please refer to FIG. 13(a) to FIG. 13(b).FIG. 13(a) is across-sectional schematic diagram of a modified N_STSCR device 500 according to the present invention.

FIG. 13(b) is a diagram of a corresponding symbol for the modified N_STSCR device 500. The modified design of the N_STSCR device is called as an N_STMLSCR device in the following. As shown in FIG. 13(a), the N_STMLSCR device 500 comprises an N⁺ diffusion 508 inserted in an N-well 502 for use as a trigger node, and a P⁺ diffusion 509 added across the junction between an N-well 502 and a P-type substrate 501 to further reduce the breakdown voltage of the SCR device.As shown in FIG. 13(b),the N_STMLSCR 500 comprises an N⁺ diffusion region 508 inserted in the N-well 502, and a P⁺ diffusion region 509 across the junction between the N-well 502 and the P-type substrate 501.

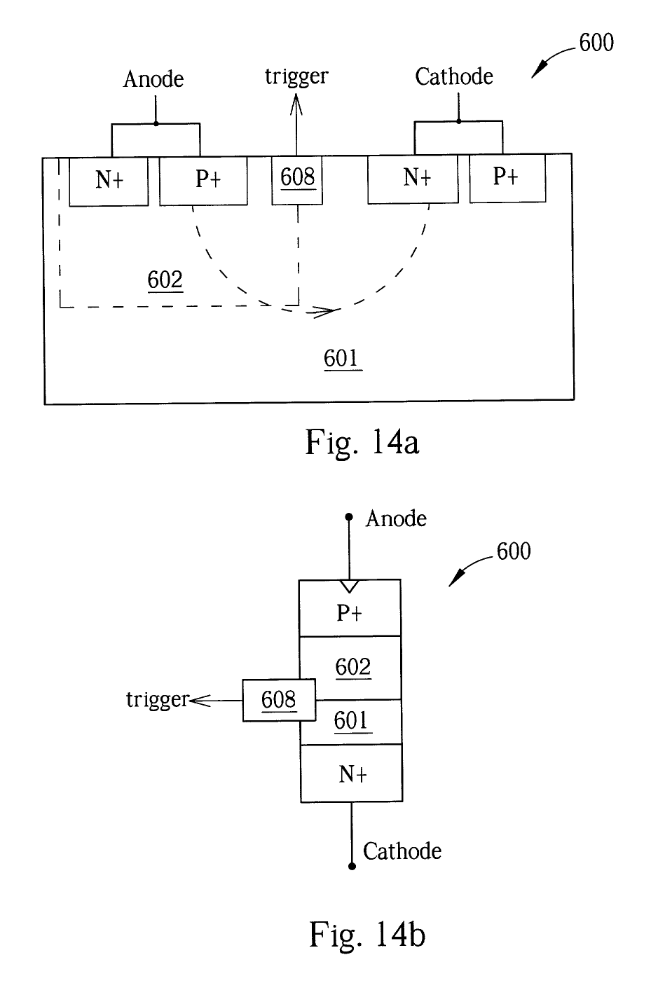

The layout spacing from the anode to the cathode of an N_STSCR device can be further reduced. Please refer to FIG. 14(a) to FIG. 14(b).FIG. 14(a) is across-sectional schematic diagram of an N_STSCR device 600 with a reduced layout spacing according to the present invention. FIG. 14(b) is a diagram of a corresponding symbol for the N_STSCR device 600. As shown in FIG. 14(a), an N diffusion region 608 is inserted as trigger node and is directly added across the junction between an N-well 602 and a P-type substrate 601. When a trigger current flows out from the trigger node 608, the SCR is triggered on. As shown in FIG. 14(b), the N_STSCR 600 comprises the N⁺ diffusion 608 inserted across the junction between the N-well 602 and the P-type substrate 601.

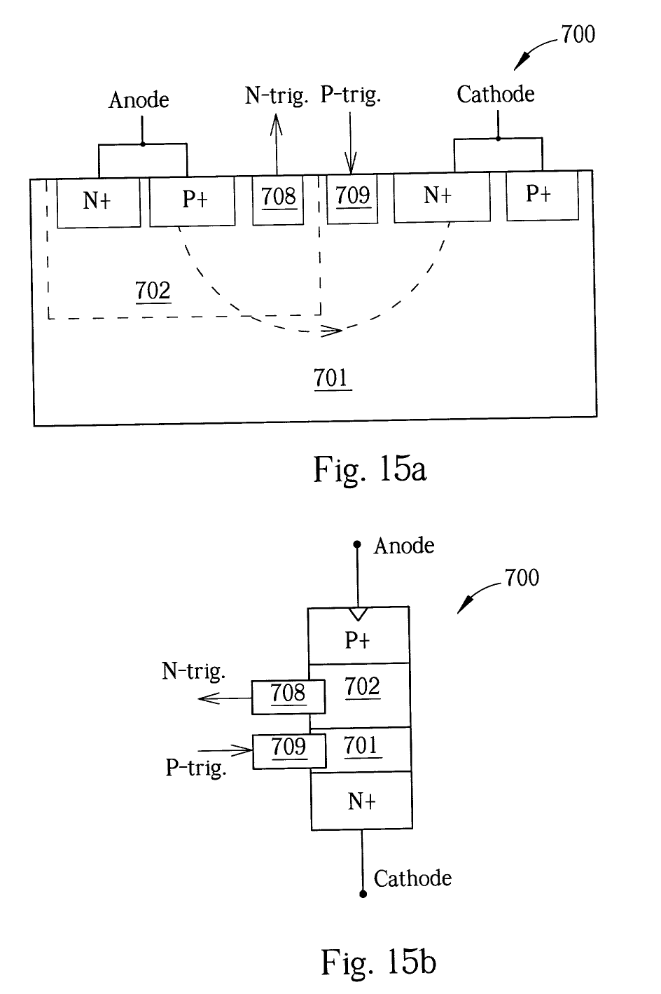

In another embodiment of the present invention, the concept of triggering on the SCR device by way of a trigger current in the P-type substrate or by way of a trigger current in the N-well can be further combined as a double-triggered SCR (DT_SCR) device. Please refer to FIG. 15(a) and FIG. 15(b).FIG. 15(a) is across-sectional schematic diagram of a double-triggered SCR device 700 according to the present invention. FIG. 15(b) is a diagram of a corresponding symbol for the double-triggered SCR device 700. As shown in FIG. 15(a), there are both an N⁺ diffusion trigger node 708 in an N-well 702, and a P⁺ diffusion trigger node 709 in a P-type substrate 701 in the DT-SCR device 700 structure. With both a trigger current into the P-type substrate 701, and a trigger current out from the N-well 702, the DT_SCR 700 has a faster turn-on speed to trigger into its latch state. This is very useful for bypassing fast transient ESD currents in ESD events. In human-body-model (HMB) ESD events, the peak ESD has a rise time of only about 10 ns. A faster turn-on speed of the DT_SCR device is better for ESD-protection purpose. As shown in FIG. 15(b), the DT_SCR 700 comprises the N⁺ diffusion trigger node 708 in the N-well 702, and the P⁺ diffusion trigger node 709 in the P-type substrate 701.

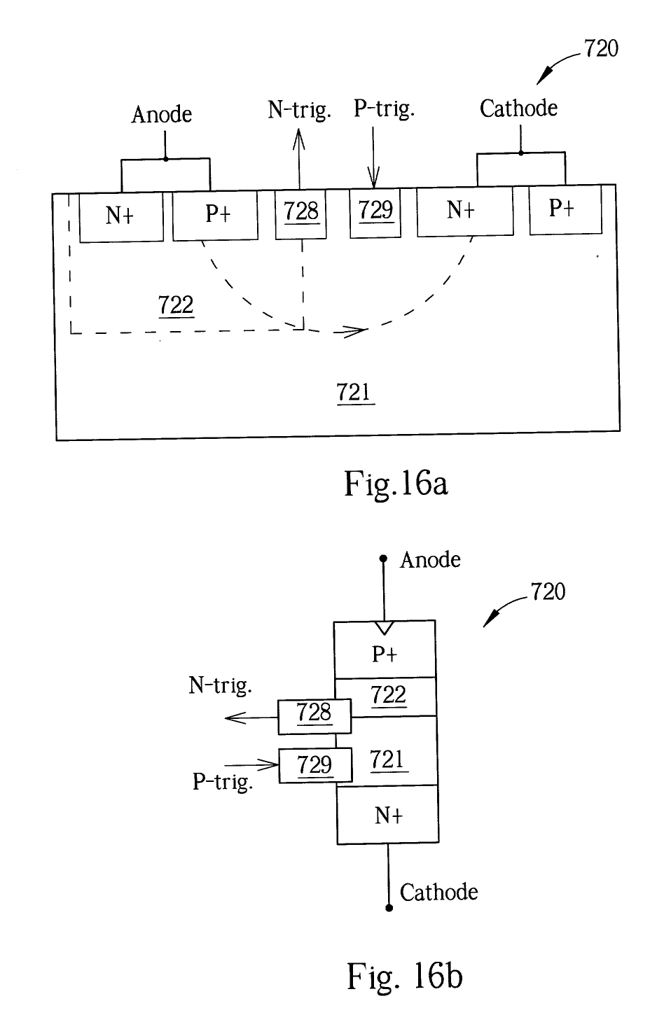

Please refer to FIG. 16(a) and FIG. 16(b). FIG. 16(a) is across-sectional schematic diagram of a modified DT_SCR device 720 according to the present invention. FIG. 16(b) is a diagram of a corresponding symbol for the modified DT_SCR device 720. As shown in FIG. 16(a), an inserted N⁺ diffusion trigger node 728 is located across the junction between an N-well 722 and a P-type substrate 721. This device has a lower junction breakdown voltage for the SCR device as compared to that of FIG. 15(a). As shown in FIG. 16(b), the modified DT_SCR 720 comprises the N⁺ diffusion trigger node 728 inserted across the junction between the N-well 722 and the P-type substrate 721, and a P⁺ diffusion trigger node 729 in the P-type substrate 721.

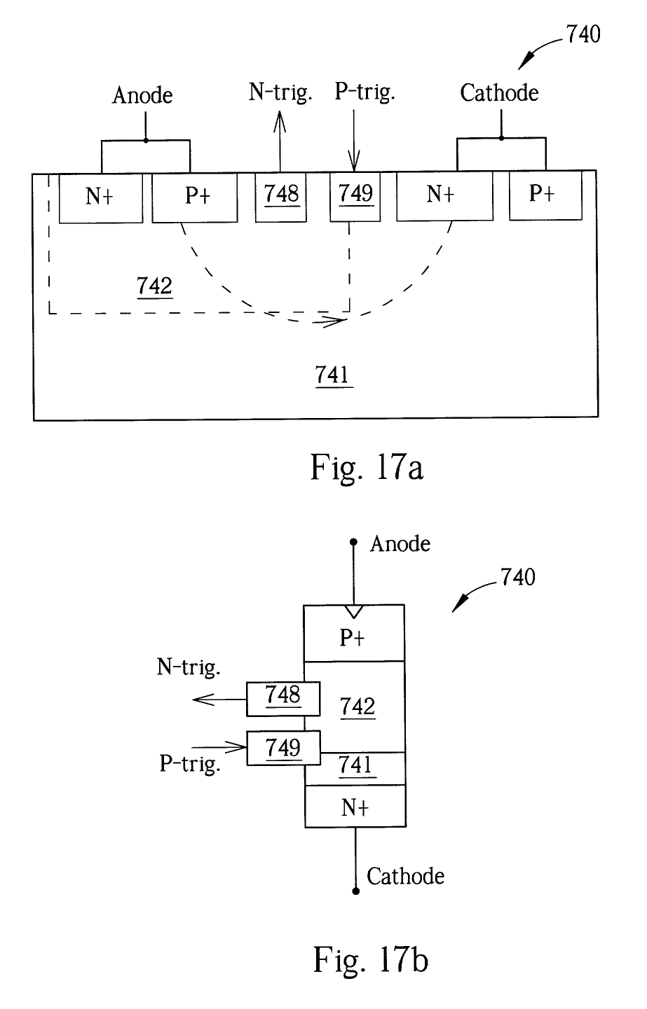

Please refer to FIG. 17(a) and FIG. 17(b). FIG. 17(a) is a cross-sectional schematic diagram of another modified DT_SCR device 740 according to the present invention. FIG. 17(b) is a diagram of a corresponding symbol for the modified DT_SCR device 740. As shown in FIG. 17(a), an inserted P⁺ diffusion trigger node 749 is located across a junction between an N-well 742 and a P-type substrate 741. This device has a lower junction breakdown voltage of the SCR device as compared to that of FIG. 15(a). As shown in FIG. 17(b), the modified DT_SCR 740 comprises an N⁺ diffusion trigger node 748 in the N-well 742, and the P⁺ diffusion trigger node 749 inserted across the junction between the N-well 742 and the P-type substrate 741.

In very deep submicron CMOS processes, the N⁺/P⁺ diffusionregion has a shallower junction depth of about 0.15˜0.2 μm from the silicon surface, but the field-oxide region to block the adjacent diffusion regions has a depth of 0.4˜0.5 μm from the silicon surface. In a sub-quarter-micron CMOS process, such as 0.18 μm CMOS process, the field oxide region is formed by way of a shallow-trench-isolation (STI) method, which often has a deeper field-oxide depth to provide better isolation between two adjacent diffusion regions. Such a deeper field-oxide region also provides better latch-up immunity to the CMOS ICs. But, the lateral SCR device structure in such an STI CMOS process has a higher holding voltage or a slower turn-on speed due to the reduced beta gain of the parasitic lateral n-p-n bipolar junction transistor (BJT) in the SCR device structure. So, the lateral SCR device becomes less effective for ESD protection if the SCR device structure has a deeper field-oxide region.

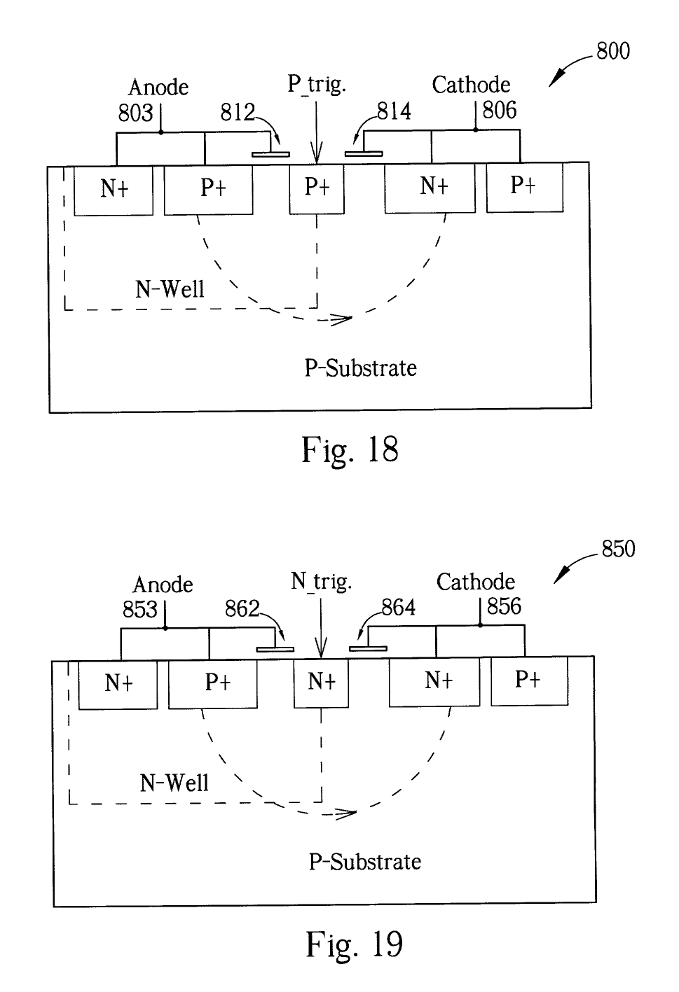

In a third embodiment of the present invention, a modified design is proposed to further reduce the turn-on time of a substrate-triggered SCR device in very deep submicron CMOS processes with deeper field-oxide region, or an advanced STI field-oxide region. Please refer to FIG. 18. FIG. 8 is a schematic diagram of a P_STSCR device 800 with a gate poly to block a field-oxide region. As shown in FIG. 18, field-oxide regions (not shown) in the SCR path between an anode 803 and a cathode 806 of the SCR device is blocked by the additional gates G1 812 and G2 814. With the additional gates 812 and 814, the deeper field-oxide regions (not shown) are blocked by the poly gate. Therefore, the turn-on speed of the substrate-triggered device is not degraded by advanced CMOS processes that utilize STI structures or deeper field-oxide regions. A similar modified design can be applied to N-type substrate-triggered SCR (N_STSCR) devices. Please refer to FIG. 19. FIG. 19 is a schematic diagram of an N_STSCR device 850 with a gate poly to block a field-oxide region. As shown in FIG. 9, additional gates G1 862 and G2 864 are used to block the growth of field-oxide regions (not shown) along the SCR path from an anode 853 to a cathode 856.

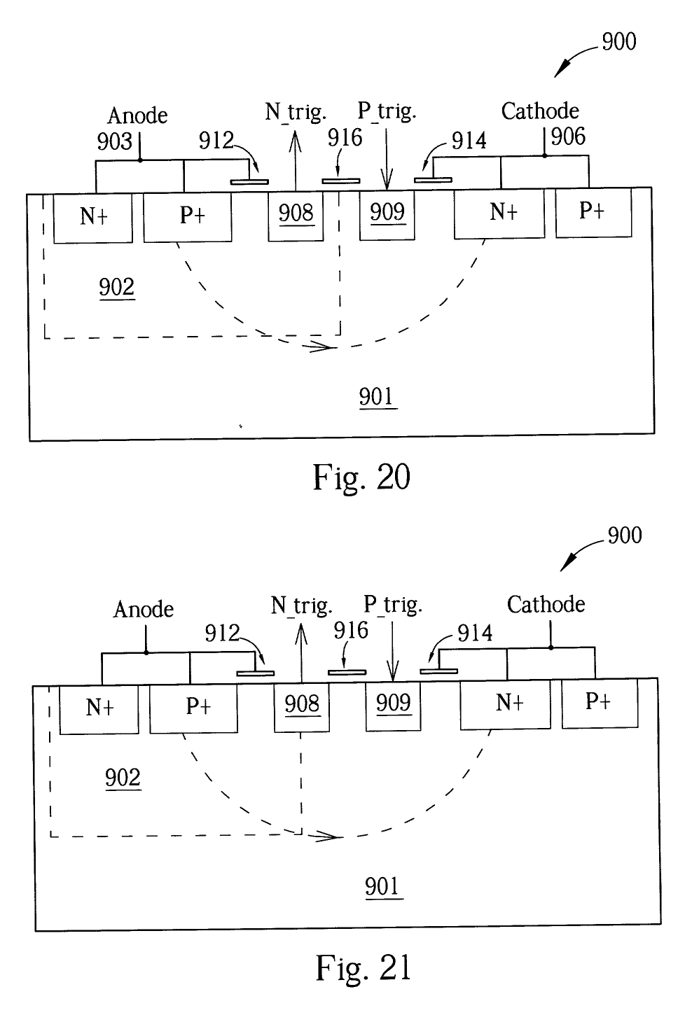

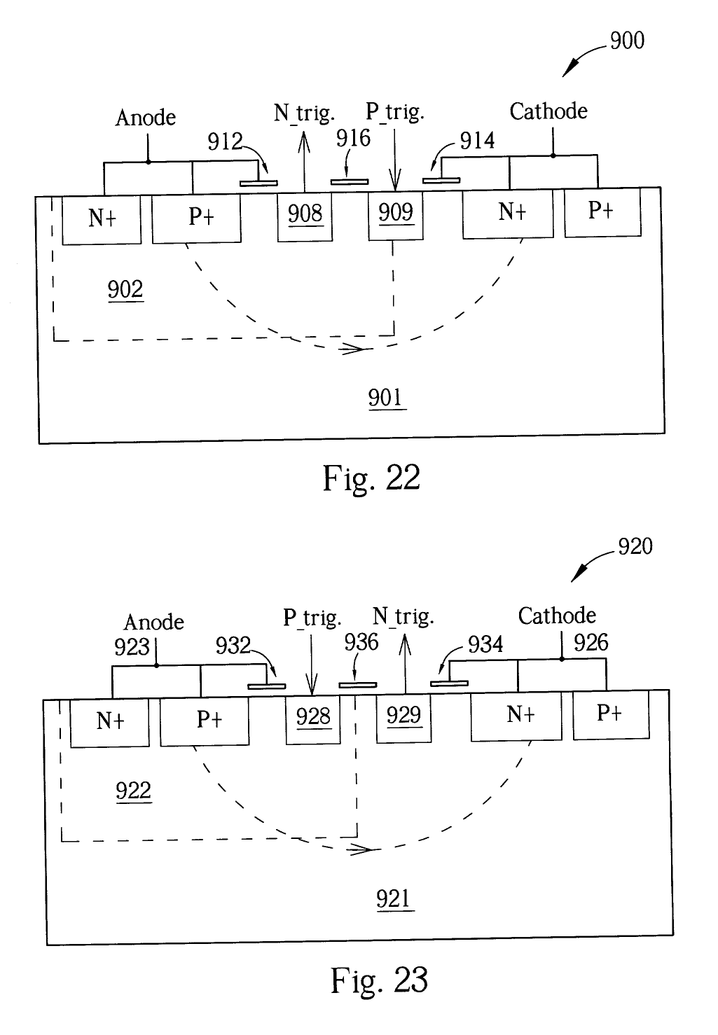

Such a design concept can also be applied to double-triggered SCR devices to block the growth of field-oxide regions along the SCR path from the anode to the cathode in advanced CMOS processes. Please refer to FIG. 20 to FIG. 22. FIG. 20 to FIG. 22 are schematic diagrams of a DT_SCR device 900 with poly gates to block field-oxide regions. As shown in FIG. 20 to FIG. 22, three additional gates G1 912, G2 914 and G3 916 are used to block the growth of field-oxide regions (not shown) along the SCR path from the anode 903 to the cathode 906. The only difference in these three designs is the different locations of the inserted N⁺ diffusion trigger node 908 and P⁺ diffusion trigger node 909. In FIG. 20, the N⁺ diffusion trigger node 908 is located in the N-well 902 and the P⁺ diffusion trigger node 909 is located in the P-type substrate 901. In FIG. 21, the N⁺ diffusion trigger node 908 is located across the junction between the N-well 902 and the P-type substrate 901, and the P⁺ diffusion trigger node 909 is located in the P-type substrate 901. In FIG. 22, the N⁺ diffusion trigger node 908 is located in the N-well 902, and the P⁺ diffusion trigger node 909 is located across the junction between the N-well 902 and the P-type substrate 901.

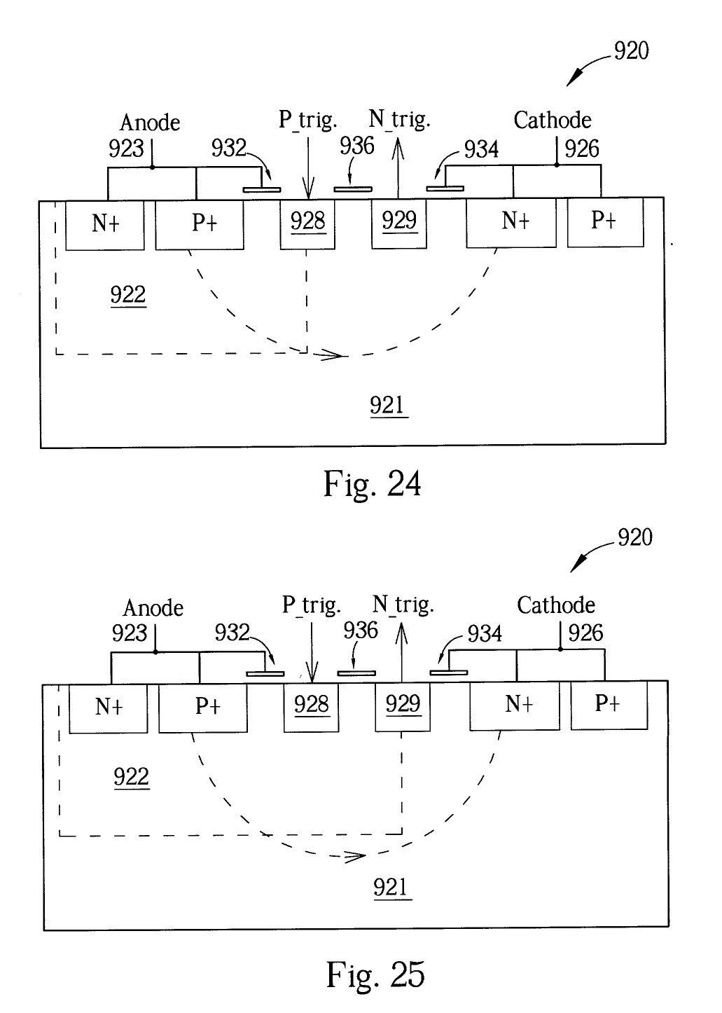

Please refer to FIG. 23 to FIG. 25. FIG. 23 to FIG. 25 are schematic diagrams of a modified DT_SCR device 920 with poly gates to block field-oxide regions. In this modified DT_SCR device structure, the trigger node in the N-well 922 is formed by a P⁺ diffusion region 928, and the trigger node in the P-type substrate 921 is formed by an N⁺ diffusion region 929. The lateral device can be turned on by a trigger current into the N-well 922 from the inserted P⁺ diffusion 928, or by a trigger current out of the P-type substrate 921 from the inserted N⁺ diffusion 929. The applied trigger currents generate current flow in the N-well 922 or P-type substrate 921, consequently triggering the SCR device into its latch state. The only difference in these three designs is the different locations of the inserted P⁺ diffusion trigger node 928 and N⁺ diffusion trigger node 929. In FIG. 23, the P⁺ diffusion trigger node 928 is located in the N-well 922, and the N⁺ diffusion trigger node 929 is located in the P-type substrate 921. In FIG. 24, the P⁺ diffusion trigger node 928 is located across the junction between the N-well 922 and the P-type substrate 921, and the N⁺ diffusion trigger node 929 is located in the P-type substrate 921. In FIG. 25, the P⁺ diffusion trigger node 928 is located in the N-well 922, and the N⁺ diffusion trigger node 929 is located across the junction between the N-well 922 and the P-type substrate 921.

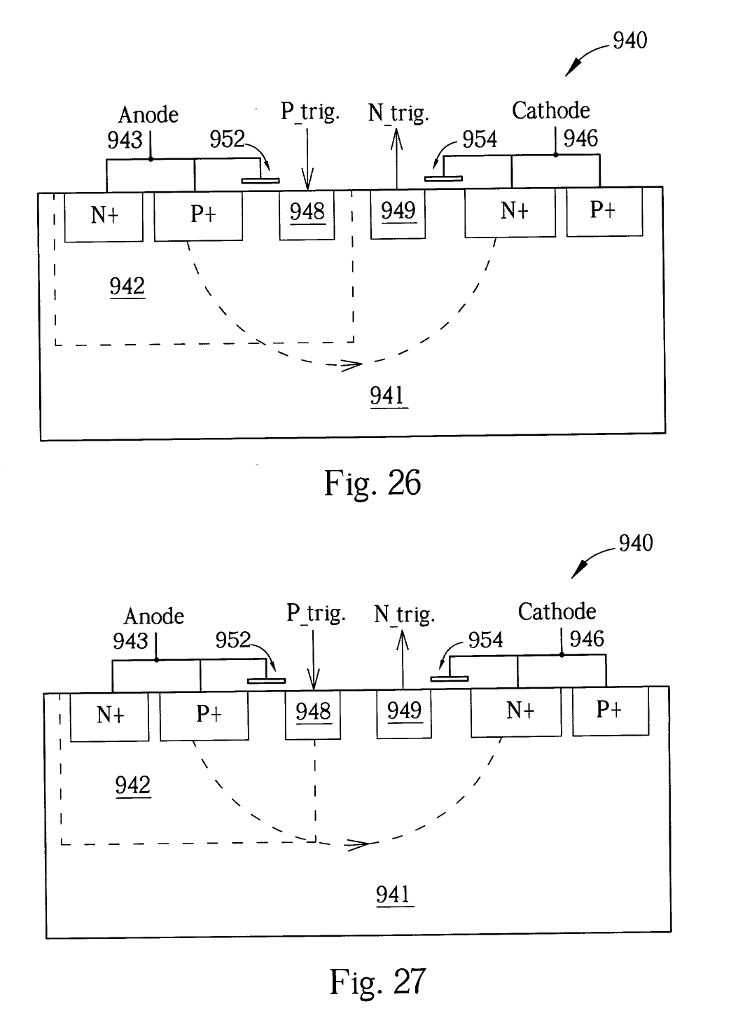

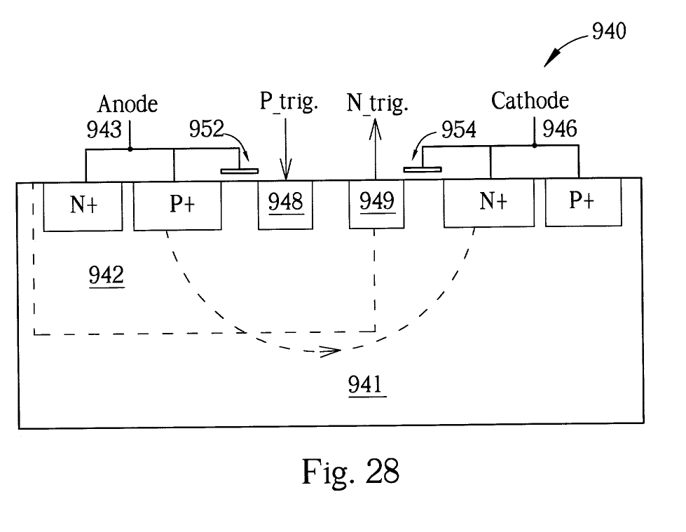

Please refer to FIG. 26 to FIG. 28. FIG. 26 to FIG. 28 are schematic diagrams of a DT_SCR device 940 with two poly gates to block field oxide regions. If the process limits formation of a gate G3 between the N⁺ diffusion trigger node 949 and the P⁺ diffusion trigger node 948 of the DT_SCR device 940 structure, a modified design with only two additional gates G1 952 and G2 954 can be used to block the growth of the field-oxide regions (not shown) from the anode 943 to the cathode 946. The only difference in these three designs is the different locations of the inserted P⁺ diffusion trigger node 948 and N⁺ diffusion trigger node 949. In FIG. 26, the P⁺ diffusion trigger node 948 is located in the N-well 942, and the N⁺ diffusion trigger node 949 is located in the P-type substrate 941. In FIG. 27, the P⁺ diffusion trigger node 948 is located across the junction between the N-well 942 and the P-type substrate 941, and the N⁺ diffusion trigger node 949 is located in the P-type substrate 941. In FIG. 28, the P⁺ diffusion trigger node 948 is located in the N-well 942, and the N⁺ diffusion trigger node 949 is located across the junction between the N-well 942 and the P-type substrate 941.

The devices shown in the present invention are all demonstrated with respect to CMOS processes utilizing N-wells and P-type substrates. The present invention can also be applied to CMOS processes that utilize twin-well processes in either P-type substrates or N-type substrates. The present invention may also be realized in CMOS processes that utilize P-wells and N-type substrates.

In summary, the method according to the present invention for making an on-chip ESD protection circuit with a substrate-triggered SCR element is to have a substrate-triggered current I_{trig} flowing into or flowing out from the P-type substrate through the trigger node. Hence, the lateral SCR will be triggered on into its latch state and lead to a much lower switching voltage in the SCR device.With such a lower switching voltage in the SCR device, the total layout area of the ESD protection circuit can be reduced, and the turn-on speed of the SCR device can be further improved to quickly discharge ESD current.Also, ESD current flowing through surface channels, and heat dissipation problems, are avoided, while the complexity and difficulty for CMOS IC manufacturing is not increased.

In contrast to the prior method of making an on-chip ESD protection circuit, the present invention utilizes a substrate-triggered current I_{trig} flowing into or flowing out from a P-type substrate or an N-well through an inserted trigger node, leading to a much lower switching voltage in the SCR device.With such a lower switching voltage in the SCR device, the total layout area of the ESD protection circuit can be reduced, and the turn-on speed of SCR device can be further improved to quickly discharge ESD current.ESD current flowing through surface channels, and heat dissipation issues, are avoided, while presenting no increase to the overall complexity and difficulty of CMOS IC manufacturing.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A P-type substrate-triggered silicon controlled rectifier (P_STSCR), the P_STSCR formed on a P-type substrate, the P_STSCR comprising:
an N-well in the P-type substrate;
a first N⁺ diffusion region and a first P⁺ diffusion region in the P-type substrate for use as a cathode of the P_STSCR;
a second N⁺ diffusion region and a second P⁺ diffusion region in the N-well for use as an anode of the P_STSCR, the second P⁺ diffusion region, the N-well, the P-type substrate and the first N⁺ diffusion region forming a lateral silicon controlled rectifier (SCR); and
a P-type trigger node for accepting a trigger current;
wherein when the trigger current flows into the P_STSCR through the P-type trigger node, the lateral SCR is triggered into a latch state.

2. The P_STSCR of claim 1 wherein the P_STSCR is used as an electrostatic discharge protection device.

3. The P_STSCR of claim 1 wherein the P-type trigger node of the P_STSCR is a third P⁺ diffusion region, the third P⁺ diffusion region disposed in the P-type substrate between the first N⁺ diffusion region and the second P⁺ diffusion region.

4. The P_STSCR of claim 1 wherein the P-type trigger node of the P_STSCR is a third P⁺ diffusion region, the third P⁺ diffusion region disposed across the N-well and the P-type substrate to lower a breakdown voltage of the lateral SCR device.

5. The P_STSCR of claim 4 wherein a first shallow trench isolation (STI) structure is formed in the N-well between the third P⁺ diffusion region and the second P⁺ diffusion region of the P_STSCR, and a second shallow trench isolation (STI) structure is formed in the P-type substrate between the third P⁺ diffusion region and the first N⁺ diffusion region.

6. The P_STSCR of claim 4 wherein a first gate is formed on the N-well between the third P⁺ diffusion region and the second P⁺ diffusion region of the P_STSCR, and a second gate is formed on the P-type substrate between the third P⁺ diffusion region and the first N⁺ diffusion region.

7. The P_STSCR of claim 6 wherein the first gate and the second gate in the P_STSCR are used to reduce a holding voltage of the P_STSCR so as to improve a turn-on speed of the P_STSCR.

8. A P-type substrate-triggered modified lateral silicon controlled rectifier (P_STMLSCR), the P_STMLSCR formed on a P-type substrate, the P_STMLSCR comprising:
an N-well in the P-type substrate;
a first N⁺ diffusion region and a first P⁺ diffusion region in the P-type substrate for use as a cathode of the P_STMLSCR;
a second N⁺ diffusion region and a second P⁺ diffusion region in the N-well for use as an anode of the P_STMLSCR, the second P⁺ diffusion region, the N-well, the P-type substrate and the first N⁺ diffusion region forming a lateral silicon controlled rectifier (SCR);
a third P⁺ diffusion region in the P-type substrate between the first N⁺ diffusion region and the second P⁺ diffusion region for use as a trigger node to accept a trigger current; and
a third N⁺ diffusion region across the N-well and the P-type substrate;
wherein when the trigger current flows into the P_STMLSCR through the trigger node, the lateral SCR is triggered into a latch state.

9. The P_STMLSCR of claim 8 wherein the third N⁺ diffusion region is used to deduce a breakdown voltage of the lateral SCR.

10. An N-type substrate-triggered silicon controlled rectifier (N_STSCR), the N_STSCR formed on a P-type substrate, the N_STSCR comprising:
an N-well in the P-type substrate;
a first N⁺ diffusion region and a first P⁺ diffusion region in the P-type substrate for use as a cathode of the N_STSCR;
a second N⁺ diffusion region and a second P⁺ diffusion region in the N-well for use as an anode of the N_STSCR, the second P⁺ diffusion region, the N-well, the P-type substrate and the first N⁺ diffusion region forming a lateral silicon controlled rectifier (SCR); and
an N-type trigger node for an out-flowing trigger current;
wherein when the trigger current flows out from the N_STSCR through the N-type trigger node, the lateral SCR is triggered into a latch state.

11. The N_STSCR of claim 10 wherein the N_STSCR is used as an electrostatic discharge protection device.

12. The N_STSCR of claim 10 wherein the N-type trigger node of the N_STSCR is a third N⁺ diffusion region, the third N⁺ diffusion region disposed in the N-well between the first N⁺ diffusion region and the second P⁺ diffusion region.

13. The N_STSCR of claim 10 wherein the N-type trigger node of the N_STSCR is a third N⁺ diffusion region, the third N⁺ diffusion region disposed across the N-well and the P-type substrate to lower a breakdown voltage of the lateral SCR device.

14. The N_STSCR of claim 13 wherein a first shallow trench isolation (STI) structure is formed in the N-well between the third N⁺ diffusion region and the second P⁺ diffusion region of the N_STSCR, and a second shallow trench isolation (STI) structure is formed in the P-type substrate between the third N diffusion region and the first N⁺ diffusion region.

15. The N_STSCR of claim 13 wherein a first gate is formed on the N-well between the third N⁺ diffusion region and the second P⁺ diffusion region of the N_STSCR, and a second gate is formed on the P-type substrate between the third N⁺ diffusion region and the first N⁺ diffusion region.

16. The N_STSCR of claim 15 wherein the first gate and the second gate in the N_STSCR are used to reduce a holding voltage of the N_STSCR so as to improve a turn-on speed of the N_STSCR.

17. An N-type substrate-triggered modified lateral silicon controlled rectifier (N_STMLSCR), the N_STMLSCR formed on a P-type substrate, the N_STMLSCR comprising:
an N-well in the P-type substrate;
a first N⁺ diffusion region and a first P⁺ diffusion region in the P-type substrate for use as a cathode of the N_STMLSCR;
a second N⁺ diffusion region and a second P⁺ diffusion region in the N-well for use as an anode of the N_STMLSCR, the second P⁺ diffusion region, the N-well, the P-type substrate and the first N⁺ diffusion region forming a lateral silicon controlled rectifier (SCR);
a third N⁺ diffusion region in the N-well between the first N⁺ diffusion region and the second P⁺ diffusion region for use as a trigger node to accept a trigger current; and
a third P⁺ diffusion region across the N-well and the P-type substrate;
wherein when the trigger current flows out from the N_STMLSCR through the trigger node, the lateral SCR is triggered into a latch state.

18. The N_STMLSCR of claim 17 wherein the third P⁺ diffusion region is used to reduce a breakdown voltage of the lateral SCR.

19. An double-triggered silicon controlled rectifier (DT_SCR), the DT_SCR formed on a P-type substrate, the DT_SCR comprising:
an N-well in the P-type substrate;
a first N⁺ diffusion region and a first P⁺ diffusion region in the P-type substrate for use as a cathode of the DT_SCR;
a second N⁺ diffusion region and a second P⁺ diffusion region in the N-well for use as an anode of the DT_SCR, the second P⁺ diffusion region, the N-well, the P-type substrate and the first N⁺ diffusion region forming a lateral silicon controlled rectifier (SCR);
a first trigger node for accepting a first trigger current; and
a second trigger node for an out-flowing second trigger current;
wherein when the first trigger current flows into the DT_SCR through the first trigger node, or when the second trigger current flows out from the DT_SCR through the second trigger node, the lateral SCR is triggered into a latch state.

20. The DT_SCR of claim 19 wherein the first trigger node of the DT_SCR is a third P⁺ diffusion region, the third P⁺ diffusion region disposed in the P-type substrate between the first N⁺ diffusion region and the second P⁺ diffusion region, and the second trigger node is a third N⁺ diffusion region, the third N⁺ region disposed in the N-well between the first N⁺ diffusion region and the second P⁺ region.

21. The DT_SCR of claim 20 wherein a first shallow trench isolation (STI) structure is formed in the N-well between the third N⁺ diffusion region and the second P⁺ diffusion region, and a second shallow trench isolation (STI) structure is formed in the P-type substrate between the third P⁺ diffusion region and the first N⁺ diffusion region.

22. The DT_SCR of claim 20 wherein a first gate is formed on the N-well between the third N⁺ diffusion region and the second P⁺ diffusion region, and a second gate is formed on the P-type substrate between the third P⁺ diffusion region and the first N⁺ diffusion region.

23. The DT_SCR of claim 22 wherein the first gate and the second gate in the DT_SCR are used to reduce a holding voltage of the DT_SCR so as to improve a turn-on speed of the DT_SCR.

24. The DT_SCR of claim 19 wherein the first trigger node of the DT_SCR is a third P⁺ diffusion region, the third P⁺ diffusion region disposed in the P-type substrate between the first N⁺ diffusion region and the second P⁺ diffusion region, and the second trigger node is a third N⁺ diffusion region, the third N region disposed across the N-well and the P-type substrate to reduce a breakdown voltage of the lateral SCR.

25. The DT_SCR of claim 24 wherein a first shallow trench isolation (STI) structure is formed in the N-well between the third N⁺ diffusion region and the second P⁺ diffusion region, and a second shallow trench isolation (STI) structure is formed in the P-type substrate between the third P⁺ diffusion region and the first N⁺ diffusion region.

26. The DT_SCR of claim 24 wherein a first gate is formed on the N-well between the third N⁺ diffusion region and the second P⁺ diffusion region, and a second gate is formed on the P-type substrate between the third P⁺ diffusion region and the first N⁺ diffusion region.

27. The DT_SCR of claim 26 wherein the first gate and the second gate are used to reduce a holding voltage of the DT_SCR so as to improve a turn-on speed of the DT_SCR.

28. The DT_SCR of claim 19 wherein the first trigger node of the DT_SCR is a third P⁺ diffusion region, the third P⁺ diffusion region disposed across the N-well and the P-type substrate to reduce a breakdown voltage of the lateral SCR, and the second trigger node is a third N⁺ diffusion region, the third N⁺ region disposed in the N-well between the first N⁺ diffusion region and the second P⁺ diffusion region.

29. The DT_SCR of claim 28 wherein a first shallow trench isolation (STI) structure is formed in the N-well between the third N⁺ diffusion region and the second P⁺ diffusion region, and a second shallow trench isolation (STI) structure is formed in the P-type substrate between the third P⁺ diffusion region and the first N⁺ diffusion region.

30. The DT_SCR of claim 28 wherein a first gate is formed on the N-well between the third N⁺ diffusion region and the second P⁺ diffusion region, and a second gate is formed on the P-type substrate between the third P⁺ diffusion region and the first N⁺ diffusion region.

31. The DT_SCR of claim 30 wherein the first gate and the second gate are used to reduce a holding voltage of the DT_SCR so as to improve a turn-on speed of the DT_SCR.

32. The DT_SCR of claim 19 wherein a third shallow trench isolation(STI) is formed between the third N⁺ diffusion region and the third P⁺ diffusion region of the DT-SCR.

33. The DT_SCR of claim 19 wherein a third gate is formed between the third N⁺ diffusion region and the third P⁺ diffusion region.

34. A double-triggered silicon controlled rectifier (DT_SCR) for quick substrate-triggering, the DT_SCR formed on a P-type substrate, the DT_SCR comprising:
an N-well in the P-type substrate;
a first N⁺ diffusion region and a first P⁺ diffusion region in the P-type substrate for use as a cathode of the DT_SCR;
a second N⁺ diffusion region and a second P⁺ diffusion region in the N-well for use as an anode of the DT_SCR, the second P⁺ diffusion region, the N-well, the P-type substrate and the first N⁺ diffusion region forming a lateral silicon controlled rectifier (SCR);
a first trigger node for accepting a first trigger current; and
a second trigger node for an out-flowing second trigger current;
wherein when the first trigger current flows into the DT_SCR through the first trigger node, or when the second trigger current flows out from the DT_SCR through the second trigger node, the lateral SCR is triggered into a latch state.

35. The DT_SCR of claim 34 wherein the first trigger node of the DT_SCR is a third P⁺ diffusion region, the third P⁺ diffusion region disposed in the N-well between the first N⁺ diffusion region and the second P⁺ diffusion region, and the second trigger node is a third N⁺ diffusion region, the third N⁺ region disposed in the P-type substrate between the first N⁺ diffusion region and the second P⁺ region.

36. The DT_SCR of claim 35 wherein a first shallow trench isolation (STI) structure is formed in the N-well between the third P⁺ diffusion region and the second P⁺ diffusion region, and a second shallow trench isolation (STI) structure is formed in the P-type substrate between the third N⁺ diffusion region and the first N⁺ diffusion region.

37. The DT_SCR of claim 35 wherein a first gate is formed on the N-well between the third P⁺ diffusion region and the second P⁺ diffusion region, and a second gate is formed on the P-type substrate between the third N⁺ diffusion region and the first N⁺ diffusion region.

38. The DT_SCR of claim 37 wherein the first gate and the second gate are used to reduce a holding voltage of the DT_SCR so as to improve a turn-on speed of the DT_SCR.

39. The DT_SCR of claim 34 wherein the first trigger node of the DT_SCR is a third N⁺ diffusion region, the third N⁺ diffusion region disposed in the P⁺ type substrate between the first N⁺ diffusion region and the second P⁺ diffusion region, and the second trigger node is a third P⁺ diffusion region, the third P⁺ region disposed across the N-well and the P-type substrate to reduce a breakdown voltage of the lateral SCR.

40. The DT_SCR of claim 39 wherein a first shallow trench isolation (STI) structure is formed in the N-well between the third P⁺ diffusion region and the second P⁺ diffusion region, and a second shallow trench isolation (STI) structure is formed in the P-type substrate between the third N⁺ diffusion region and the first N⁺ diffusion region.

41. The DT_SCR of claim 39 wherein a first gate is formed on the N-well between the third P⁺ diffusion region and the second P⁺ diffusion region, and a second gate is formed on the P-type substrate between the third N⁺ diffusion region and the first N⁺ diffusion region.

42. The DT_SCR of claim 41 wherein the first gate and the second gate are used to reduce a holding voltage of the DT_SCR so as to improve a turn-on speed of the DT_SCR.

43. The DT_SCR of claim 34 wherein the first trigger node of the DT_SCR is a third N⁺ diffusion region, the third N⁺ diffusion region disposed across the N-well and the P-type substrate to reduce a breakdown voltage of the lateral SCR, and the second trigger node is a third P⁺ diffusion region, the third P⁺ region disposed in the N-well between the first N⁺ diffusion region and the second P⁺ diffusion region.

44. The DT_SCR of claim 43 wherein a first shallow trench isolation (STI) structure is formed in the N-well between the third P⁺ diffusion region and the second P⁺ diffusion region, and a second shallow trench isolation (STI) structure is formed in the P-type substrate between the third N⁺ diffusion region and the first N⁺ diffusion region.

45. The DT_SCR of claim 43 wherein a first gate is formed on the N-well between the third P⁺ diffusion region and the second P⁺ diffusion region, and a second gate is formed on the P-type substrate between the third N⁺ diffusion region and the first N⁺ diffusion region.

46. The DT_SCR of claim 45 wherein the first gate and the second gate in the DT_SCR are used to reduce a holding voltage of the DT_SCR so as to improve a turn-on speed of the DT_SCR.

47. The DT_SCR of claim 34 wherein a third shallow trench isolation (STI) structure is formed between the third N⁺ diffusion region and the third P⁺ diffusion.

48. The DT_SCR of claim 34 wherein a third gate is formed between the third N⁺ diffusion region and the third P⁺ diffusion region.
